(19) United States
(12) Patent Application Publication
(10) Pub. No.: US 2025/0349681 A1
(43) Pub. Date: Nov. 13, 2025

(54) SUBSTRATE STRUCTURE

(71) Applicant: Unimicron Technology Corp., Taoyuan City (TW)

(72) Inventors: Chin-Sheng Wang, Taoyuan City (TW); Ra-Min Tain, Hsinchu County (TW)

(73) Assignee: Unimicron Technology Corp., Taoyuan City (TW)

(21) Appl. No.: 19/232,886

(22) Filed: Jun. 10, 2025

Related U.S. Application Data
(63) Continuation-in-part of application No. 19/174,951, filed on Apr. 10, 2025.
Application No. 19/174,951 is a continuation-in-part of application No. 18/668,275, filed on May 20, 2024.
(60) Provisional application No. 63/643,932, filed on May 8, 2024.
(60) Provisional application No. 63/658,882, filed on Jun. 12, 2024.
(60) Provisional application No. 63/668,792, filed on Jul. 9, 2024.

(30) Foreign Application Priority Data
Dec. 31, 2024 (TW) 113151809
May 7, 2025 (TW) 114117084

(51) Int. Cl. H01L 23/498; H01L 23/00; H01L 23/31

(52) U.S. Cl. CPC H01L 23/49811; H01L 23/31; H01L 24/02; H01L 24/16; H01L 2224/02185; H01L 2224/16145; H01L 2224/16225

(57) ABSTRACT

A substrate structure includes a first substrate, a second substrate, a plurality of conductive bumps, a plurality of nano-metal wires, and an electroless metal material. The first substrate includes a plurality of first pads. The second substrate includes a plurality of second pads, in which the second pads are respectively disposed corresponding to the first pads. The conductive bumps are disposed on at least one of the first pads and the second pads. The nano-metal wires are disposed on the conductive bumps, or disposed on the first pads or the second pads which are not disposed with the conductive bumps. The electroless metal material is disposed between the first substrate and the second substrate, and directly covers the conductive bumps and the nano-metal wires. The first pads of the first substrate are electrically connected to the second pads of the second substrate at least by the electroless metal material.

### CROSS-REFERENCE TO RELATED APPLICATION

This application is a continuation-in-part application of and claims the priority benefit of U.S. application Ser. No. 19/174,951, filed on Apr. 10, 2025, which is a continuation-in-part application of and claims the priority benefit of U.S. application Ser. No. 18/668,275, filed on May 20, 2024, and also claims the priority benefits of U.S. Provisional Application No. 63/643,932, filed on May 8, 2024, U.S. Provisional Application No. 63/658,882, filed on Jun. 12, 2024, and Taiwan application serial no. 113151809, filed on Dec. 31, 2024. This application also claims the priority benefits of U.S. provisional application Ser. No. 63/668,792, filed on Jul. 9, 2024, and Taiwan application serial no. 114117084, filed on May 7, 2025. The entirety of each of the above-mentioned patent applications is hereby incorporated by reference herein and made a part of this specification.

### BACKGROUND

### Technical Field

The disclosure relates to a substrate structure, and particularly relates to a substrate structure with better electrical property reliability.

### Related Art

Currently, the electrical connection between two substrates is mainly through bumps disposed on pads. However, due to insufficient alignment precision, high-precision micro bumps have poor bonding yield, which affects the electrical property reliability of the substrate structure.

### SUMMARY

The disclosure provides a substrate structure with better electrical property reliability.

The substrate structure of the disclosure includes a first substrate, a second substrate, a plurality of conductive bumps, a plurality of nano-metal wires, and an electroless metal material. The first substrate includes a plurality of first pads. The second substrate includes a plurality of second pads, in which the second pads are respectively disposed corresponding to the first pads. The conductive bumps are disposed on at least one of the first pads and the second pads. The nano-metal wires are disposed on the conductive bumps, or disposed on the first pads or the second pads which are not disposed with the conductive bumps. The electroless metal material is disposed between the first substrate and the second substrate, and directly covers the conductive bumps and the nano-metal wires. The first pads of the first substrate are electrically connected to the second pads of the second substrate at least by the electroless metal material.

In an embodiment of the disclosure, the substrate structure further includes an underfill filled in between the first substrate and the second substrate, and directly covering the electroless metal material.

In an embodiment of the disclosure, the substrate structure further includes a first solder resist layer and a second solder resist layer. The first solder resist layer is disposed on the first substrate, and covers part of the first pads. The second solder resist layer is disposed on the second substrate, and covers part of the second pads.

In an embodiment of the disclosure, the conductive bumps include a first conductive bump, a second conductive bump, and a third conductive bump. A first height of the first conductive bump is greater than a second height of the second conductive bump. A third height of the third conductive bump is less than the second height of the second conductive bump.

In an embodiment of the disclosure, the nano-metal wires are disposed on the second pads, while the first conductive bump, the second conductive bump, and the third conductive bump are disposed on the first pads respectively.

In an embodiment of the disclosure, the first conductive bump squeezes the corresponding nano-metal wires.

In an embodiment of the disclosure, the second conductive bump is in contact with the corresponding nano-metal wires by surface.

In an embodiment of the disclosure, the third conductive bump is not in contact with the corresponding nano-metal wires.

In an embodiment of the disclosure, the conductive bumps further include multiple fourth conductive bumps having the same height.

In an embodiment of the disclosure, the fourth conductive bumps are disposed on the first pads, while the first conductive bump, the second conductive bump, and the third conductive bump are disposed on the second pads respectively. The nano-metal wires are disposed on the first conductive bump, the second conductive bump, the third conductive bump, and the fourth conductive bumps.

In an embodiment of the disclosure, the nano-metal wires located on the first conductive bump and the nano-metal wires located on the corresponding fourth conductive bump are interlaced and intertwined with each other.

In an embodiment of the disclosure, the nano-metal wires located on the second conductive bump are in contact with the nano-metal wires located on the corresponding fourth conductive bump.

In an embodiment of the disclosure, the nano-metal wires located on the third conductive bump are not in contact with the nano-metal wires located on the corresponding fourth conductive bump.

In an embodiment of the disclosure, the electroless metal material includes electroless copper, electroless nickel, or electroless gold.

In an embodiment of the disclosure, a projection surface area of each conductive bump on the first substrate is smaller than a projection surface area of each first pad on the first substrate.

In an embodiment of the disclosure, a height of each nano-metal wire is in a range of 1 micrometer to 50 micrometers.

Based on the above, in the design of the substrate structure of the disclosure, the electroless metal material is disposed between the first substrate and the second substrate, and directly covers the conductive bumps and nano-metal wires located on the first pads and/or the second pads, in which the first pads of the first substrate are electrically connected to the second pads of the second substrate at least by the electroless metal material. In other words, the first pads and the second pads may be bonded through metal-to-metal diffusion bonding between the conductive bumps and the nano-metal wires, or through metal-to-metal diffusion bonding between the nano-metal wires, or through the electroless metal material filling the gaps between the conductive bumps and the nano-metal wires, or through a combination of the above, to increase the bonding yield between the first pads and the second pads, thereby enabling the substrate structure of the disclosure to have better electrical reliability.

To make the foregoing features and advantages of the disclosure more comprehensible, embodiments are specifically provided below, with detailed explanations in conjunction with the accompanying drawings as follows.

### BRIEF DESCRIPTION OF THE DRAWINGS

FIG. 1A to FIG. 1F are cross-section schematic diagrams of a substrate structure according to an embodiment of the disclosure.

FIG. 2A to FIG. 2D are cross-section schematic diagrams of partial steps of the substrate structure according to another embodiment of the disclosure.

### DESCRIPTION OF THE EMBODIMENTS

The embodiments of the disclosure may be understood in conjunction with the drawings, and the drawings of the disclosure are also considered as part of the disclosure. It should be understood that the drawings of the disclosure are not drawn to scale; in fact, the dimensions of the elements may be arbitrarily enlarged or reduced to clearly present the features of the disclosure.

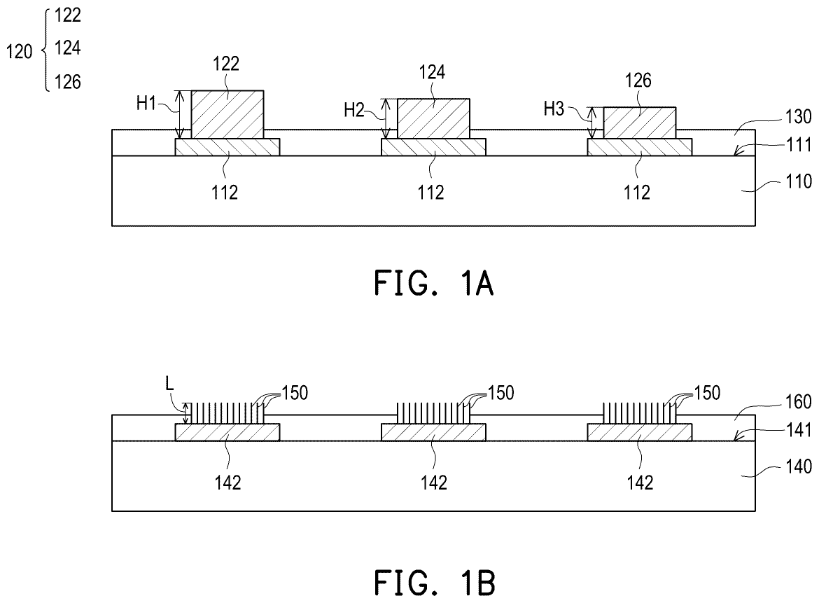

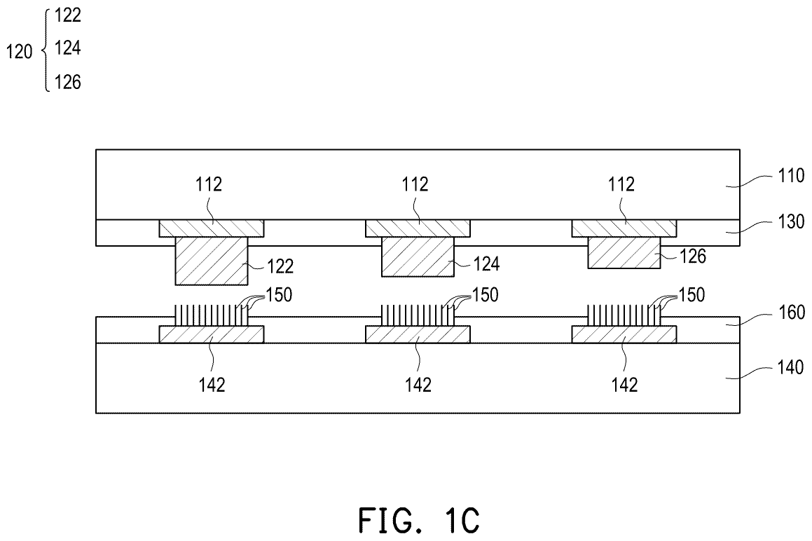

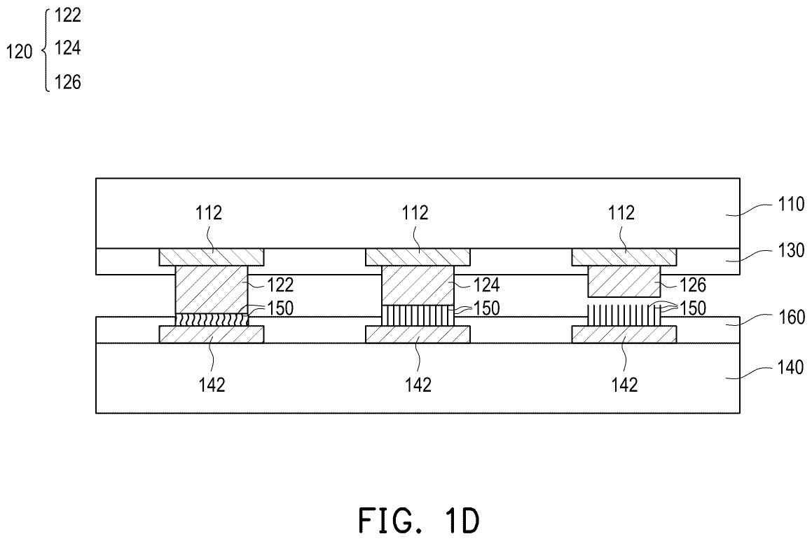

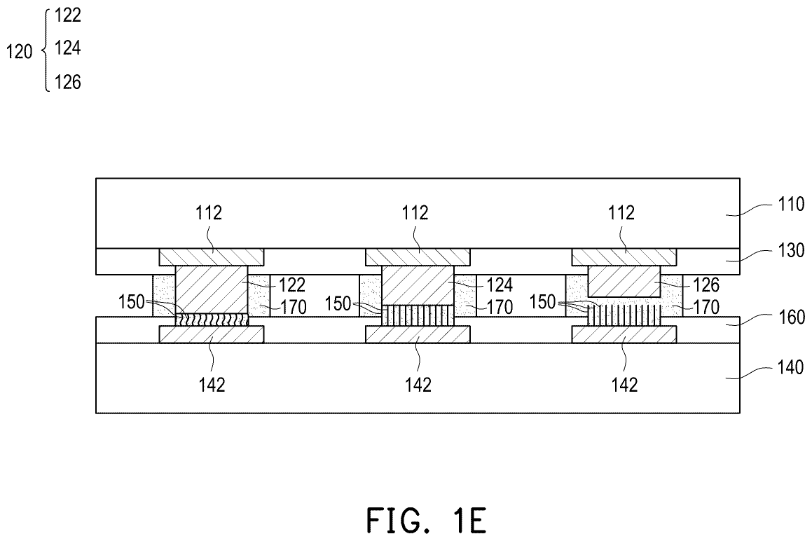

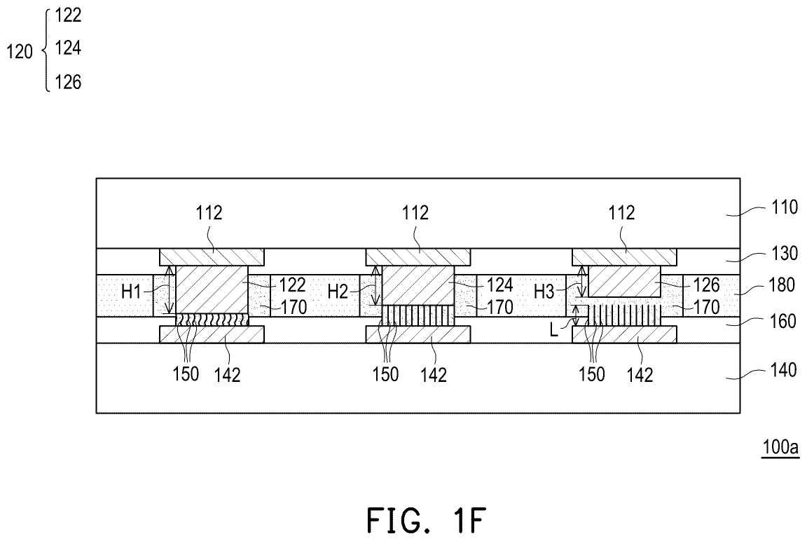

FIG. 1A to FIG. 1F are cross-section schematic diagrams of a substrate structure according to an embodiment of the disclosure. According to a manufacturing method of the substrate structure of this embodiment, first, referring to FIG. 1A, a first substrate 110 is provided. In an embodiment, the first substrate 110 may be, for example, an organic substrate or an inorganic substrate. In an embodiment, the organic substrate is, for example, a glass fiber resin (such as FR4) substrate, a Prepreg (PP) substrate, or an inorganic filler mixed in resin (such as Ajinomoto build-up film, ABF) substrate, but the disclosure is not limited thereto. In an embodiment, the inorganic substrate is, for example, a glass substrate, a ceramic substrate, a glass-ceramic substrate, or a semiconductor substrate, but the disclosure is not limited thereto. In an embodiment, the first substrate 110 is, for example, a multi-layer circuit substrate.

Next, an electroplating seed layer (not shown) is formed on a first surface 111 of the first substrate 110, in which the electroplating seed layer completely covers the first surface 111. In an embodiment, the material of the electroplating seed layer is, for example, titanium/copper or copper, but the disclosure is not limited thereto. Next, multiple mutually separated first pads 112 are formed on the electroplating seed layer, and conductive bumps 120 are respectively formed on these first pads 112, in which the conductive bumps 120 are electrically connected to the corresponding first pads 112. That is, the first pad 112 and the corresponding conductive bump 120 are two independently formed components. In an embodiment, a projection surface area of each conductive bump 120 on the first substrate 110 is smaller than a projection surface area of each first pad 112 on the first substrate 110. In an embodiment, a height of each conductive bump 120 is greater than a height of each first pad 112. In an embodiment, a material of the first pad 112 is exemplified by copper, and a material of the conductive bump 120 is, for example, copper, but the disclosure is not limited thereto.

Furthermore, in this embodiment, the conductive bumps 120 include a first conductive bump 122, a second conductive bump 124, and a third conductive bump 126. In an embodiment, the first conductive bump 122, the second conductive bump 124, and the third conductive bump 126 have different heights. In an embodiment, a first height H1 of the first conductive bump 122 is greater than a second height H2 of the second conductive bump 124, and a third height H3 of the third conductive bump 126 is less than the second height H2 of the second conductive bump 124. In an embodiment, a height difference between the first conductive bump 122 and the second conductive bump 124 may be equal to or greater than or smaller than a height difference between the second conductive bump 124 and the third conductive bump 126. In an embodiment, the first conductive bump 122, the second conductive bump 124, and the third conductive bump 126 may have the same height.

Next, the electroplating seed layer exposed outside the first pads 112 is removed, thereby exposing the first surface 111 of the first substrate 110. Next, referring to FIG. 1A again, a first solder resist layer 130 is formed on the first surface 111 of the first substrate 110, and covers part of upper surfaces of the first pads 112 and part of surrounding surfaces of the conductive bumps 120.

Next, referring to FIG. 1B, a second substrate 140 is provided. In an embodiment, the second substrate 140 may be, for example, an organic substrate or an inorganic substrate. In an embodiment, the organic substrate is, for example, a glass fiber resin (such as FR4) substrate, a Prepreg (PP) substrate, or an inorganic filler mixed in resin (such as Ajinomoto build-up film, ABF) substrate, but the disclosure is not limited thereto. In an embodiment, the inorganic substrate is, for example, a glass substrate, a ceramic substrate, a glass-ceramic substrate, or a semiconductor substrate, but the disclosure is not limited thereto. In an embodiment, the second substrate 140 is, for example, a multi-layer circuit substrate. In an embodiment, a material of the second substrate 140 is different from a material of the first substrate 110. In an embodiment, the material of the second substrate 140 is the same as the material of the first substrate 110.

Next, an electroplating seed layer (not shown) is formed on a second surface 141 of the second substrate 140, in which the electroplating seed layer completely covers the second surface 141. In an embodiment, the material of the electroplating seed layer is, for example, titanium/copper or copper, but the disclosure is not limited thereto. Next, multiple mutually separated second pads 142 are formed on the electroplating seed layer. In an embodiment, the material of the second pads 142 is, for example, copper, but the disclosure is not limited thereto.

Next, referring to FIG. 1B, multiple nano-metal wires 150 are formed by electroplating on the second pads 142, in which the nano-metal wires 150 are electrically connected to the corresponding second pads 142. In an embodiment, the material of the nano-metal wires 150 is, for example, copper, but the disclosure is not limited thereto. In an embodiment, heights L of the nano-metal wires 150 may be the same or different. In an embodiment, the height L of each nano-metal wire 150 is, for example, 1 micrometer to 50 micrometers. In an embodiment, the diameter of each nano-metal wire 150 is, for example, 4 nanometers to 4 micrometers.

Next, referring to FIG. 1B again, the electroplating seed layer exposed outside the second pads 142 is removed, thereby exposing the second surface 141 of the second substrate 140. And then, a second solder resist layer 160 is formed on the second surface 141 of the second substrate 140, and covers part of upper surfaces of the second pads 142.

Next, referring to FIG. 1C, the first substrate 110 is placed above the second substrate 140, so that the first pads 112 are respectively disposed corresponding to the second pads 142. At this time, the conductive bumps 120 on the first pads 112 face toward the nano-metal wires 150 on the second pads 142 and are disposed corresponding to each other. The first solder resist layer 130 and the second solder resist layer 160 are located between the first substrate 110 and the second substrate 140.

Next, referring to FIG. 1D, through heating and pressurizing methods, the first substrate 110 is pressed onto the second substrate 140, so that the first substrate 110 is bonded to the second substrate 140. Since the first conductive bump 122, the second conductive bump 124, and the third conductive bump 126 have different heights respectively, when the first substrate 110 is bonded to the second substrate 140, the first conductive bump 122 may squeeze the corresponding nano-metal wires 150, while the second conductive bump 124 may be in contact with the corresponding nano-metal wires 150 by surface, and the third conductive bump 126 may not be in contact with the corresponding nano-metal wires 150. That is, the first conductive bump 122 squeezes the corresponding nano-metal wires 150, that is, transitional contact, causing the nano-metal wires 150 to deform, resulting in a larger contact area with the second pad 142, which may improve the electrical bonding yield, in which the first conductive bump 122 and the nano-metal wires 150 are combined together through metal-to-metal diffusion, thereby electrically connecting the corresponding first pad 112 and second pad 142. The second conductive bump 124 contacts one end of the nano-metal wires 150 with a surface thereof facing the nano-metal wires 150, that is, just contact, in which the second conductive bump 124 and the nano-metal wires 150 are combined together through metal-to-metal diffusion, thereby electrically connecting the corresponding first pad 112 and second pad 142. In short, the first pad 112 and the second pad 142 may be electrically connected through the first conductive bump 122 contacting the corresponding nano-metal wires 150 and the second conductive bump 124 contacting the corresponding nano-metal wires 150. At this time, there is an air gap between the third conductive bump 126 and the corresponding nano-metal wires 150, and there is no electrical connection therebetween.

Afterward, referring to FIG. 1E, an electroless plating process is performed to form an electroless metal material 170 between the first substrate 110 and the second substrate 140, in which the electroless metal material 170 directly covers the conductive bumps 120 and the nano-metal wires 150. The electroless metal material 170 directly contacts and covers surrounding surfaces of the first conductive bump 122 exposed from the first solder resist layer 130 and the corresponding nano-metal wires 150, and fills the gap between the corresponding nano-metal wires 150, thereby allowing the corresponding first pad 112 to be electrically connected to the corresponding second pad 142 through the electroless metal material 170. The electroless metal material 170 directly contacts and covers surrounding surfaces of the second conductive bump 124 exposed from the first solder resist layer 130 and the corresponding nano-metal wires 150, and fills the gap between the corresponding nano-metal wires 150, thereby allowing the corresponding first pad 112 to be electrically connected to the corresponding second pad 142 through the electroless metal material 170. The electroless metal material 170 directly contacts and covers surrounding surfaces of the third conductive bump 126 exposed from the first solder resist layer 130 and the corresponding nano-metal wires 150, and fills the gap between the corresponding nano-metal wires 150 and the air gap between the third conductive bump 126 and the nano-metal wires 150, thereby allowing the corresponding first pad 112 to be electrically connected to the corresponding second pad 142 through the electroless metal material 170.

In other words, when the first pad 112 and the second pad 142 are already electrically conductive through the contacting first conductive bump 122 with the corresponding nano-metal wires 150 and the second conductive bump 124 with the corresponding nano-metal wires 150, the electroless metal material 170 may further enhance the electrical conduction effect; when the third conductive bump 126 and the corresponding nano-metal wires 150 are not in contact and no electrical connection is formed between the first pad 112 and the second pad 142, the disposition of the electroless metal material 170 may electrically connect the third conductive bump 126 and the corresponding nano-metal wires 150, thereby allowing the first pad 112 and the second pad 142 to be electrically connected through the electroless metal material 170. In one embodiment, the projection surface area of the electroless metal material 170 on the first substrate 110 is larger than the area of the first pad 112, and the electroless metal material 170 exposes part of the first solder resist layer 130 and part of the second solder resist layer 160. In one embodiment, the electroless metal material 170 may be electroless copper, electroless nickel, or electroless gold.

Finally, referring to FIG. 1F, an underfill 180 may be optionally included to fill in between the first substrate 110 and the second substrate 140, and to cover the electroless metal material 170, in order to enhance the bonding strength between the first substrate 110 and the second substrate 140, as well as to protect the conductive structure covered by the electroless metal material 170. At this point, the fabrication of a substrate structure 100a is completed.

Structurally, referring again to FIG. 1F, the substrate structure 100a includes the first substrate 110, the second substrate 140, the multiple conductive bumps 120, the multiple nano-metal wires 150, and the electroless metal material 170. The first substrate 110 includes the multiple first pads 112. The second substrate 140 includes the multiple second pads 142, in which the second pads 142 are disposed corresponding to the first pads 112. The conductive bumps 120 are disposed on the first pads 112. The nano-metal wires 150 are disposed on the second pads 142 which are not disposed with the conductive bumps 120. The electroless metal material 170 is disposed between the first substrate 110 and the second substrate 140, and directly covers the conductive bumps 120 and the nano-metal wires 150. The first pads 112 of the first substrate 110 are electrically connected to the second pads 142 of the second substrate 140 at least by the electroless metal material 170.

Furthermore, in this embodiment, the conductive bumps 120 include the first conductive bump 122, the second conductive bump 124, and the third conductive bump 126. The first height H1 of the first conductive bump 122 is greater than the second height H2 of the second conductive bump 124. The third height H3 of the third conductive bump 126 is less than the second height H2 of the second conductive bump 124. The nano-metal wires 150 are disposed on the second pads 142, while the first conductive bump 122, the second conductive bump 124, and the third conductive bump 126 are respectively disposed on the first pads 112. The first conductive bump 122 squeezes the corresponding nano-metal wires 150, while the second conductive bump 124 is in contact with the corresponding nano-metal wires 150 by surface, and the third conductive bump 126 is not in contact with the corresponding nano-metal wires 150. In one embodiment, the projection surface area of each conductive bump 120 on the first substrate 110 is smaller than the projection surface area of each first pad 112 on the first substrate 110. In one embodiment, the height L of each nano-metal wire 150 is in a range of 1 micrometer to 50 micrometers. In one embodiment, the electroless metal material 170 may be, for example, electroless copper, electroless nickel, or electroless gold.

In addition, the substrate structure 100a of this embodiment further includes the first solder resist layer 130 and the second solder resist layer 160. The first solder resist layer 130 is disposed on the first substrate 110, and covers part of the first pads 112 and part of the surrounding surfaces of the first conductive bump 122, part of the surrounding surfaces of the second conductive bump 124, and part of the surrounding surfaces of the third conductive bump 126. The second solder resist layer 160 is disposed on the second substrate 140, and covers part of the second pads 142. Furthermore, the substrate structure 100a of this embodiment further includes the underfill 180 to fill in between the first substrate 110 and the second substrate 140, and directly covers the electroless metal material 170.

In brief, in this embodiment, the first pads and the second pads may be bonded through metal-to-metal diffusion bonding between the conductive bumps 120 and the nano-metal wires 150, or through metal-to-metal diffusion bonding between the nano-metal wires 150, or through the electroless metal material 170 filling the gaps between the conductive bumps 120 and the nano-metal wires 150, or through a combination of the above, to increase the bonding yield between the first pads 112 and the second pads 142, thereby enabling the substrate structure 100a of this embodiment to have better electrical property reliability.

The following will list other embodiments for illustration. It should be explained that the following embodiments use the reference numerals and part of the content from the previous embodiments, where the same reference numerals are used to represent the same or similar components, and explanations of identical technical content are omitted. For explanations of the omitted parts, please refer to the previous embodiments, as details will not be repeated in the following embodiments.

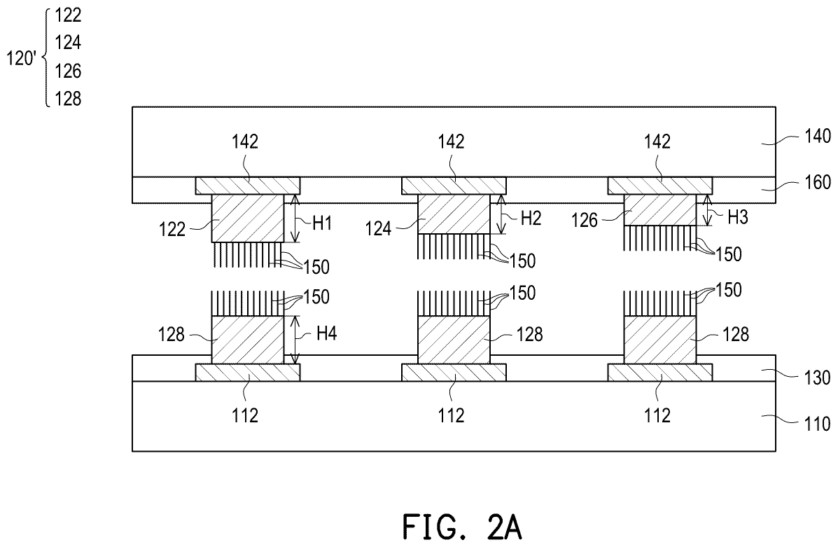

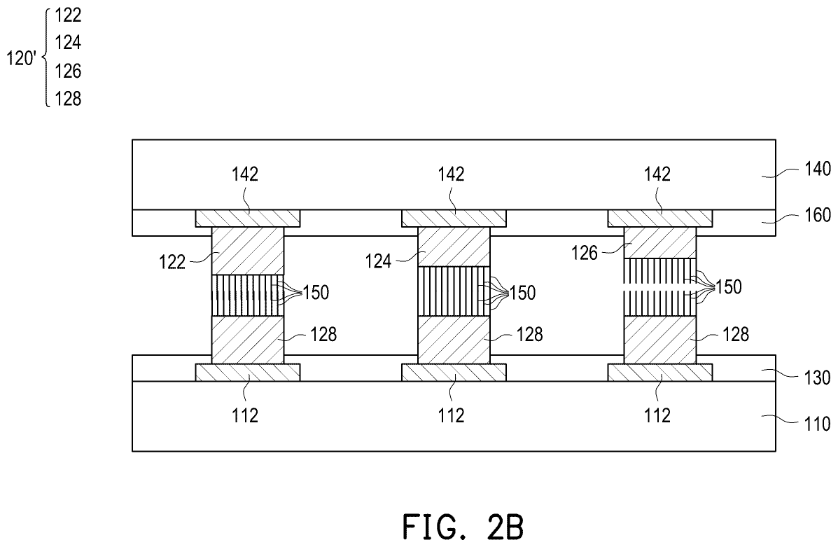

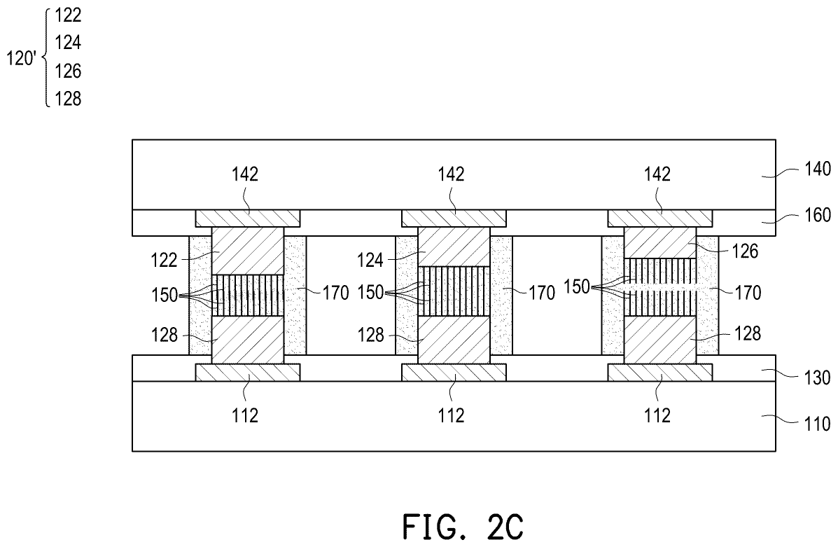

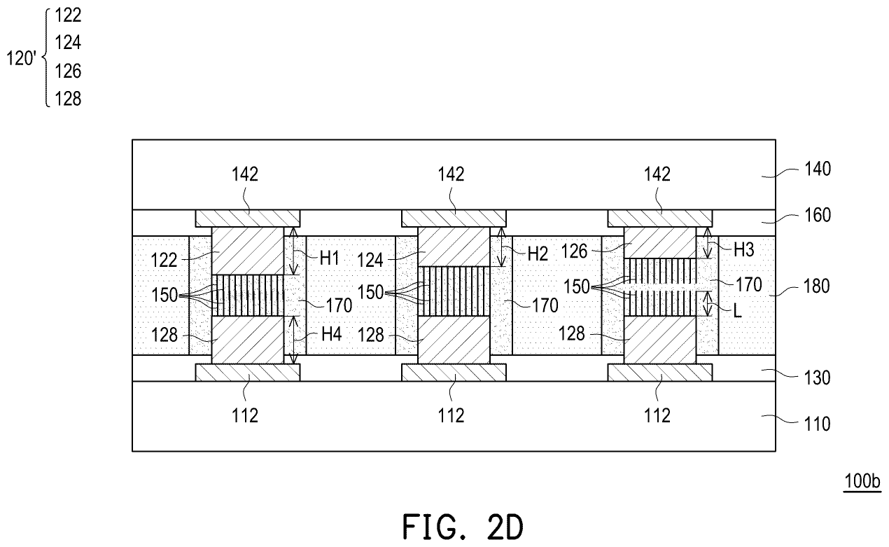

FIG. 2A to FIG. 2D are cross-sectional schematic diagrams of partial steps of the substrate structure according to another embodiment of the disclosure. Referring to FIG. 1C and FIG. 2A simultaneously, the manufacturing method of the substrate structure in this embodiment is similar to the manufacturing method of the substrate structure described above, but the main difference between the two methods is that, in this embodiment, conductive bumps 120′ further include multiple fourth conductive bumps 128 having the same height. Specifically, the fourth conductive bumps 128 are formed on the first pads 112 of the first substrate 110, and each fourth conductive bump 128 has a fourth height H4. The first conductive bump 122, the second conductive bump 124, and the third conductive bump 126 are formed on the second pads 142 of the second substrate 140 respectively. In one embodiment, the fourth height H4 may be the same as or different from the first height H1. The nano-metal wires 150 are formed on the first conductive bump 122, the second conductive bump 124, the third conductive bump 126, and the fourth conductive bumps 128.

Subsequently, a first solder resist layer 130 is formed on the first substrate 110, and covers part of the upper surfaces of the first pads 112 and part of surrounding surfaces of the fourth conductive bumps 128. A second solder resist layer 160 is formed on the second substrate 140, and covers part of the upper surfaces of the second pads 142 and part of the surrounding surfaces of the first conductive bump 122, part of the surrounding surfaces of the second conductive bump 124, and part of the surrounding surfaces of the third conductive bump 126. Subsequently, the second substrate 140 is placed above the first substrate 110, so that the second pads 142 are disposed corresponding to the first pads 122.

Next, referring to FIG. 2B, through heating and pressurizing methods, the second substrate 140 is pressed onto the first substrate 110, so that the second substrate 140 is bonded to the first substrate 110. Since the first conductive bump 122, the second conductive bump 124, and the third conductive bump 126 have different heights respectively, when the second substrate 140 is bonded to the first substrate 110, the nano-metal wires 150 on the first conductive bump 122 may squeeze the nano-metal wires 150 on the corresponding fourth conductive bumps 128, while the nano-metal wires 150 on the second conductive bump 124 may just contact the nano-metal wires 150 on the corresponding fourth conductive bumps 128, and the nano-metal wires 150 on the third conductive bump 126 may not be in contact with the nano-metal wires 150 on the corresponding fourth conductive bumps 128. Furthermore, the nano-metal wires 150 located on the first conductive bump 122 and the nano-metal wires 150 located on the corresponding fourth conductive bump 128 are interlaced and intertwined with each other. The nano-metal wires 150 located on the second conductive bump 124 just contact the nano-metal wires 150 located on the corresponding fourth conductive bump 128. The nano-metal wires 150 located on the third conductive bump 126 are not in contact with the nano-metal wires 150 located on the corresponding fourth conductive bump 128. In short, the first pads 112 and the second pads 142 may be electrically connected through the contact between the nano-metal wires 150 on the first conductive bump 122 and the nano-metal wires 150 on the corresponding fourth conductive bumps 128, as well as the contact between the nano-metal wires 150 on the second conductive bump 124 and the nano-metal wires 150 on the corresponding fourth conductive bumps 128. At this time, there is an air gap between the nano-metal wires 150 on the third conductive bump 126 and the nano-metal wires 150 on the corresponding fourth conductive bumps 128, and there is no electrical connection therebetween.

Afterward, referring to FIG. 2C, an electroless plating process is performed to form an electroless metal material 170 between the first substrate 110 and the second substrate 140, in which the electroless metal material 170 directly covers the conductive bumps 120′ and the nano-metal wires 150. The electroless metal material 170 directly contacts and covers the surrounding surfaces of the first conductive bump 122 exposed from the second solder resist layer 160 and the corresponding nano-metal wires 150, the surrounding surfaces of the fourth conductive bump 128 exposed from the first solder resist layer 130 and the corresponding nano-metal wires 150, and fills the gap between the nano-metal wires 150, thereby allowing the corresponding second pad 142 to be electrically connected to the corresponding first pad 112 through the electroless metal material 170. The electroless metal material 170 directly contacts and covers the surrounding surfaces of the second conductive bump 124 exposed from the second solder resist layer 160 and the corresponding nano-metal wires 150, the surrounding surfaces of the fourth conductive bump 128 exposed from the first solder resist layer 130 and the corresponding nano-metal wires 150, and fills the gap between the corresponding nano-metal wires 150, thereby allowing the corresponding second pad 142 to be electrically connected to the corresponding first pad 112 through the electroless metal material 170. The electroless metal material 170 directly contacts and covers the surrounding surfaces of the third conductive bump 126 exposed from the second solder resist layer 160 and the corresponding nano-metal wires 150, the surrounding surfaces of the fourth conductive bump 128 exposed from the first solder resist layer 130 and the corresponding nano-metal wires 150, and fills the gap and air gap between the corresponding nano-metal wires 150, thereby allowing the corresponding second pad 142 to be electrically connected to the corresponding first pad 112 through the electroless metal material 170. In one embodiment, the electroless metal material 170 may be electroless copper, electroless nickel, or electroless gold.

Finally, referring to FIG. 2D, an underfill 180 may be optionally included to fill in between the first substrate 110 and the second substrate 140, and to cover the electroless metal material 170, in order to enhance the bonding strength between the first substrate 110 and the second substrate 140, as well as to protect the conductive structure covered by the electroless metal material 170. At this point, the fabrication of a substrate structure 100b is completed.

Structurally, referring to both FIG. 1F and FIG. 2D, the substrate structure 100b of this embodiment is similar to the substrate structure 100a, but the main difference between the two structures is that, in this embodiment, the conductive bumps 120′ further include multiple fourth conductive bumps 128 having the same height (that is, the fourth height H4). Specifically, the fourth conductive bumps 128 are disposed on the first pad 112, while the first conductive bump 122, the second conductive bump 124, and the third conductive bump 126 are disposed on the second pad 142, respectively. The nano-metal wires 150 are disposed on the first conductive bump 122, the second conductive bump 124, the third conductive bump 126, and the fourth conductive bump 128. The nano-metal wires 150 located on the first conductive bump 122 and the nano-metal wires 150 located on the corresponding fourth conductive bump 128 are interlaced and intertwined with each other. The nano-metal wires 150 located on the second conductive bump 124 are in contact with the nano-metal wires 150 located on the corresponding fourth conductive bump 128. The nano-metal wires 150 located on the third conductive bump 126 are not in contact with the nano-metal wires 150 located on the corresponding fourth conductive bump 128. The electroless metal material 170 is disposed between the first substrate 110 and the second substrate 140, and directly covers the conductive bumps 120′ and the nano-metal wires 150. The first pads 112 of the first substrate 110 are electrically connected to the second pads 142 of the second substrate 140 at least by the electroless metal material 170.

In other words, when the first pad 112 and the second pad 142 are already electrically conductive through the contacting nano-metal wires 150, the electroless metal material 170 may further enhance the electrical conduction effect; when the nano-metal wires 150 do not contact each other and no electrical connection is formed between the first pad 112 and the second pad 142, the disposition of the electroless metal material 170 may electrically connect the nano-metal wires 150, thereby allowing the first pad 112 and the second pad 142 to be electrically connected through the electroless metal material 170.

In brief, the conductive bumps 120, 120′ may be disposed on at least one of the first pad 112 and the second pad 142. The nano-metal wires 150 may be disposed on the conductive bumps 120, 120′, or disposed on the first pads 112 or the second pads 142 which are not disposed with the conductive bumps 120, 120′. The electroless metal material 170 is disposed between the first substrate 110 and the second substrate 140, and directly covers the conductive bumps 120, 120′ and the nano-metal wires 150. The first pad 112 of the first substrate 110 is electrically connected to the second pad 142 of the second substrate 140 at least by the electroless metal material 170.

In summary, in the design of the substrate structure of the disclosure, the electroless metal material is disposed between the first substrate and the second substrate, and directly covers the conductive bumps and nano-metal wires located on the first pads and/or the second pads, in which the first pads of the first substrate are electrically connected to the second pads of the second substrate at least by the electroless metal material. In other words, the first pads and the second pads may be bonded through metal-to-metal diffusion bonding between the conductive bumps and the nano-metal wires, or through metal-to-metal diffusion bonding between the nano-metal wires, or through the electroless metal material filling the gaps between the conductive bumps and the nano-metal wires, or through a combination of the above, to increase the bonding yield between the first pads and the second pads, thereby enabling the substrate structure of the disclosure to have better electrical reliability.

Although the disclosure has been disclosed in the embodiments as above, the embodiments are not intended to limit the disclosure. Persons with ordinary knowledge in the technical field may make some changes and modifications without departing from the spirit and scope of the disclosure. Therefore, the protection scope of the disclosure shall be defined by the appended claims.

What is claimed is:

1. A substrate structure, comprising:
a first substrate comprising a plurality of first pads;
a second substrate comprising a plurality of second pads, wherein the second pads are respectively disposed corresponding to the first pads;
a plurality of conductive bumps disposed on at least one of the first pads and the second pads;
a plurality of nano-metal wires disposed on the conductive bumps, or disposed on the first pads or the second pads which are not disposed with the conductive bumps; and
an electroless metal material disposed between the first substrate and the second substrate, and directly covering the conductive bumps and the nano-metal wires, wherein the first pads of the first substrate are electrically connected to the second pads of the second substrate at least by the electroless metal material.

2. The substrate structure as claimed in claim 1, further comprising:
an underfill filled in between the first substrate and the second substrate, and directly covering the electroless metal material.

3. The substrate structure as claimed in claim 1, further comprising:
a first solder resist layer disposed on the first substrate, and covering part of the first pads; and
a second solder resist layer disposed on the second substrate, and covering part of the second pads.

4. The substrate structure as claimed in claim 1, wherein the conductive bumps comprise a first conductive bump, a second conductive bump, and a third conductive bump, a first height of the first conductive bump is greater than a second height of the second conductive bump, and a third height of the third conductive bump is less than the second height of the second conductive bump.

5. The substrate structure as claimed in claim 4, wherein the nano-metal wires are disposed on the second pads, while the first conductive bump, the second conductive bump, and the third conductive bump are disposed on the first pads respectively.

6. The substrate structure as claimed in claim 5, wherein the first conductive bump squeezes corresponding ones of the nano-metal wires.

7. The substrate structure as claimed in claim 5, wherein the second conductive bump is in contact with corresponding ones of the nano-metal wires by surface.

8. The substrate structure as claimed in claim 5, wherein the third conductive bump is not in contact with corresponding ones of the nano-metal wires.

9. The substrate structure as claimed in claim 4, wherein the conductive bumps further comprise a plurality of fourth conductive bumps having same height.

10. The substrate structure as claimed in claim 9, wherein the fourth conductive bumps are disposed on the first pads, while the first conductive bump, the second conductive bump, and the third conductive bump are disposed on the second pads respectively, and the nano-metal wires are disposed on the first conductive bump, the second conductive bump, the third conductive bump, and the fourth conductive bumps.

11. The substrate structure as claimed in claim 10, wherein the nano-metal wires located on the first conductive bump and the nano-metal wires located on a corresponding one of the fourth conductive bumps are interlaced and intertwined with each other.

12. The substrate structure as claimed in claim 10, wherein the nano-metal wires located on the second conductive bump are in contact with the nano-metal wires located on a corresponding one of the fourth conductive bumps.

13. The substrate structure as claimed in claim 10, wherein the nano-metal wires located on the third conductive bump are not in contact with the nano-metal wires located on a corresponding one of the fourth conductive bumps.

14. The substrate structure as claimed in claim 1, wherein the electroless metal material comprises electroless copper, electroless nickel, or electroless gold.

15. The substrate structure as claimed in claim 1, wherein a projection surface area of each of the conductive bumps on the first substrate is smaller than a projection surface area of each of the first pads on the first substrate.

16. The substrate structure as claimed in claim 1, wherein a height of each of the nano-metal wires is in a range of 1 micrometer to 50 micrometers.
